(19) United States
(12) Patent Application Publication
(10) Pub. No.: US 2006/0156115 A1
(43) Pub. Date: Jul. 13, 2006

(54) Device, system, and method for providing error information in XHT network

(75) Inventors: Jin-hee Kim, Yongin-si (KR); Lye-suk Lee, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS, CO., LTD.

(21) Appl. No.: 11/311,380

(22) Filed: Dec. 20, 2005

(30) Foreign Application Priority Data
Dec. 29, 2004 (KR) 10-2004-0115237

(51) Int. Cl. G01R 31/28

(52) U.S. Cl. 714/724

(57) ABSTRACT

A device, a system, and a method for displaying error information within an expandable Home Theater (XHT) network, and more particularly, to a device, a system, and a method for providing error information within the XHT network by displaying error information of slave devices in the XHT network to a user through a master device having a display function are provided. The system providing error information within an XHT network upon a user's request for device error information of a slave device connected to a master device through a communication control line within the XHT network, the system including a master device requesting error information from the slave device connected through the XHT network, and a slave device transmitting the error information to the master device.

### CROSS-REFERENCE TO RELATED APPLICATION

This application claims priority from Korean Patent Application No. 10-2004-0115237 filed on Dec. 29, 2004 in the Korean Intellectual Property Office, the disclosure of which is incorporated herein by reference in its entirety.

### BACKGROUND OF THE INVENTION

1. Field of the Invention

Apparatuses, systems and methods consistent with the present invention relate to displaying error information within an eXpandable Home Theater (XHT) network, and more particularly, to providing error information within an XHT network by displaying error information of slave devices in the XHT network to a user through a master device having a display function.

2. Description of the Related Art

In recent years, with the rapid advancement in digital audio/video (A/V) processing technology, the use of a wide variety of A/V devices such as digital televisions (DTVs), set-top boxes (STBs), DVD players, and digital amplifiers is becoming prevalent at homes or offices.

Users at home or in the office have become able to conveniently control the devices at a remote location using a remote controller.

However, as the number of A/V devices installed within a given space increases, it becomes more complicated and difficult to control the respective devices. Moreover, in an event where a malfunction or an operational error occurs to an A/V device, a user may not recognize occurrence of an error until the A/V device is attempted to operate.

European Patent No. 0949625A1 discloses a method and device for checking errors by displaying error check images on a TV screen when an error check mode is selected among modes displayed on the TV screen and performing error checking on a device connected to a TV. However, the proposed method and device have a drawback in that an error test operator must individually run an error program for checking an error of each device.

### SUMMARY OF THE INVENTION

The present invention provides a method and a device for displaying error information of devices in an XHT network to a user through a master device having a display function.

The present invention also provides a method for allowing a master device to control slave devices, which includes a master device receiving a key signal generated by a user, interpreting the key signal and transmitting a user's command to an appropriate slave device.

The present invention also provides a method for allowing a device to periodically check existence of an error at predetermined time intervals and providing error information to a master device when an error has occurred.

The above stated aspects as well as other aspects, features and advantages, of the present invention will become clear to those skilled in the art upon review of the following description.

According to an aspect of the present invention, there is provided a master device existing on an XHT network, including: a key input unit that receives a key code value generated by a user; a transceiver that transmits a signal requesting error information to at least one of slave devices connected to the master device through the XHT network and receives the error information in response to the request signal; an interpreter that interprets the error information; and a display that displays the interpreted error information on a screen of the mater device. The interpreter may comprise an Extensible Markup Language (XML) interpreter.

According to another aspect of the present invention, there is provided a slave device existing on an XHT network, including a device error checking unit that checks existence of an error; an error information generator; and a transceiver that provides to at least one of master devices connected to the slave device through the XHT network. The error information generator may comprise an XML generator that creates error information in an XML format.

According to still another aspect of the present invention, there is provided a system providing error information within an XHT network upon a user's request for device error information of a slave device connected to a master device through a communication control line within the XHT network, the system including a master device requesting error information from the slave device connected through the XHT network; and a slave device transmitting the error information to the master device.

According to a further aspect of the present invention, there is provided a method for providing error information within an XHT network, the method including a slave device checking existence of an error; transmitting error information, when an error has occurred, to a master device connected with the slave device through a communication control line within the XHT network, and interpreting the error information of the slave device and displaying the same on a screen of the master device.

### BRIEF DESCRIPTION OF THE DRAWINGS

The above and other aspects of the present invention will become more apparent by describing in detail exemplary embodiments thereof with reference to the attached drawings in which:

FIG. 1A shows an example of DeviceInfo.xml file created for each device according to DeviceInfo.xsd syntax rules and FIG. 1B shows an example of XHT931.xml file created for each device according to XHT931.xsd syntax rules;

FIG. 2A shows an example of a system providing error information within an XHT network according to an exemplary embodiment of the present invention and FIGS. 2B and 2C show examples of connecting a master device with slave devices through 1394 connection lines according to exemplary embodiments of the present invention;

FIG. 3 is a block diagram of a master device in an XHT network providing error information according to an exemplary embodiment of the present invention;

FIG. 4 is a block diagram of a slave device in an XHT network providing error information according to an exemplary embodiment of the present invention;

FIG. 5 shows an example of displaying predetermined slave devices existing within an XHT network on a screen of a master device in the XHT network providing error information according to an exemplary embodiment of the present invention;

FIG. 6 shows examples of displaying error information on a screen of a device within a XHT network providing error information according to an exemplary embodiment of the present invention;

FIG. 7 is a flowchart illustrating a process of a slave device providing error information upon request from a master device in a method of providing error information within an XHT network according to an exemplary embodiment of the present invention; and

FIG. 8 is a flowchart illustrating a process of a slave device providing error information to a master device after periodically checking existence of an error in a method of providing error information within an XHT network according to an exemplary embodiment of the present invention.

### DETAILED DESCRIPTION OF THE EXEMPLARY EMBODIMENTS

The present invention may be understood more readily by reference to the following detailed description of exemplary embodiments and the accompanying drawings. The present invention may, however, be embodied in many different forms and should not be construed as being limited to the exemplary embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

The present invention will now be described more fully with reference to the accompanying drawings, in which exemplary embodiments of the invention are shown.

Standard of the XHT technology that is about middleware for A/V home networking have been developed and proposed by Samsung Electronics. The XHT technology, a DTV home network solution developed by Samsung Electronics Co., Ltd., has also been approved by Consumer Electronics Association (CEA) of the United States as a new industry standard.

The XHT technology uses IEEE 1394 cables that can deliver high definition (HD) signals and the Internet Protocol that is a communication protocol commonly used on the Internet to enable control of an A/V device connected to a DTV as well as a plurality of DTVs. For example, the XHT technology may allow viewers to watch digital broadcasts in a main room using a digital broadcasting reception function of a DTV in a living room.

A low-cost network interface unit (N) using an XHT technology is a memory card that can be easily changed depending on the type of reception (terrestrial, satellite, and cable), thereby reducing economic burden to broadcasters. In particular, the XHT technology enables a user to access a wide variety of portable services through a browser embedded in a DTV. Exemplary operations of A/V devices in an XHT network implemented using the XHT technology are described as follows:

First, a local IP address is automatically assigned to each of A/V devices in the XHT network by a predetermined address allocation algorithm. Then, each of the A/V devices assigned a local IP address describes its device information in the form of Extensible Markup Language (XML) file (DeviceInfo.xml) created according to a syntax formalism (defined in DeviceInfo.xsd file) and transmits the device information to other A/V devices. The DeviceInfo.xml file specifies a Uniform Resource Identifier (URI) of a file (XHT931.xsd) describing a set of Hypertext Transfer Protocol (HTTP) commands for operating the A/V device.

The A/V device that generated the DeviceInfo.xml file also creates an XML file (XHT931.xml) specifying it's supported HTTP commands using an XML file (XHT931.xsd) and transmits the XML file (XHT931.xml) to other A/V devices.

An A/V device that received DeviceInfo.xml and XHT931.xml files respectively specifying the device information and supported HTTP commands identifies information of the A/V device that sent the files to control the A/V device using the HTTP commands.

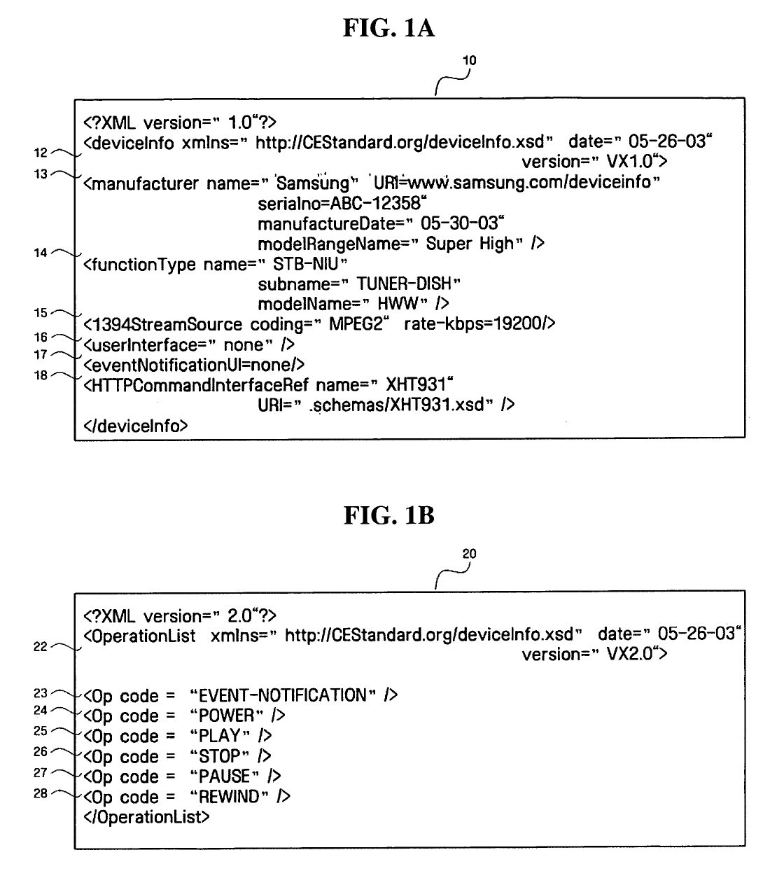

FIG. 1A shows an example of a DeviceInfo.xml file 10 generated for each device according to syntax rules defined in DeviceInfo.xsd.

Referring to FIG. 1A, a deviceInfo tag 12 specifies the location, date, and version of the deviceInfo.xsd file 10 and a manufacturer tag 13 defines the name of manufacturer, URI, and manufacture date. A functionType tag 14 specifies the function name, subname, and model number of a product and 1394StreamSource tag 15 defines a stream coding algorithm and stream bit-rate.

A userInterface tag 16 describes information about a user interface (UI) and eventNotificationUI tag 17 specifies event notification UI designed to inform a user of occurrence of event. FIG. 1A shows that no user interface function is supported.

An HTTPCommandInterfaceRef tag 18 specifies the name of XHT standard supporting HTTP commands and a URI of a file (XHT931.xsd) defining the HTTP commands.

FIG. 1B shows an example of an XHT931.xml file generated for each device according to syntax rules specified in XHT931.xsd.

Referring to FIG. 1B, an OperationList tag 22 specifies the URI, date, and version of a referenced XHT931.xsd file, followed by Op code tags specifying operation codes supported by the A/V device. In the embodiment shown in FIG. 1B, the A/V device supports the following functions: EVENT-NOTIFICATION 23 for informing another A/V device that a change in the state of the device occurs, POWER 24 for turning the power on or off, PLAY 25 for playing back a specified content, STOP 26 for stopping the content being played, PAUSE 27 for temporarily pausing the content being played, and REWIND 28 for rewinding the content.

If a first A/V device that received DeviceInfo.xml and XHT931.xml files desires to control a second A/V device that sent the XML files, the first A/V device uses an HTTP command that combines a URI with the operation code to control the second A/V device.

For example, it is assumed that the first and second A/V devices are respectively a DTV and a slave device storing a transport stream (TS) and a user uses a remote control to control a DTV so that it displays a program contained in the TS. If an IP address assigned to the slave device is 192.168.0.2, the DTV simply transmits an HTTP command “http://192.168.0.2/CEA931?play&press” to the slave device.

An A/V device compliant with the XHT standard includes a web server and a device controller converting an HTTP command into a device operation command. Thus, the slave device can perform operation corresponding to the received HTTP command. That is, the slave device transmits the TS to the DTV using an IEEE 1394 network and the DTV decodes the TS for display to the user.

Using the XHT technology in this way facilitates communication among and control of a plurality of A/V devices. By controlling one of the plurality of A/V devices, the user can efficiently control the remaining A/V devices.

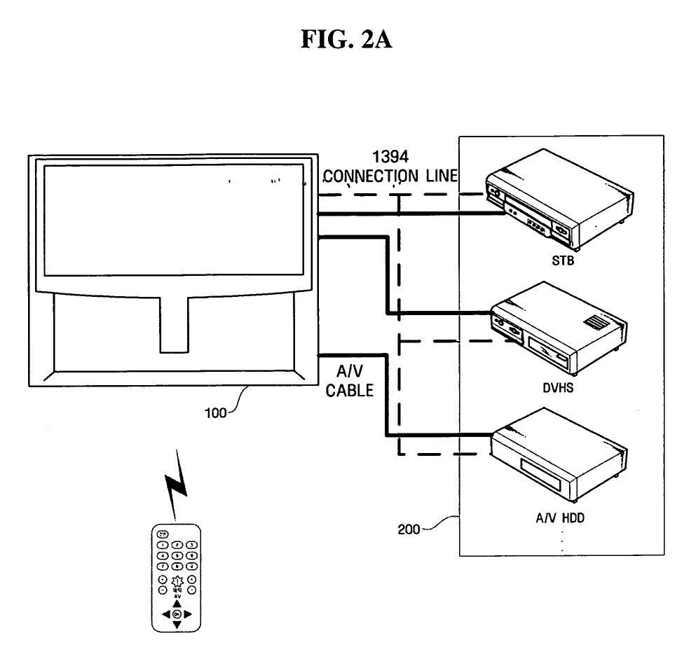

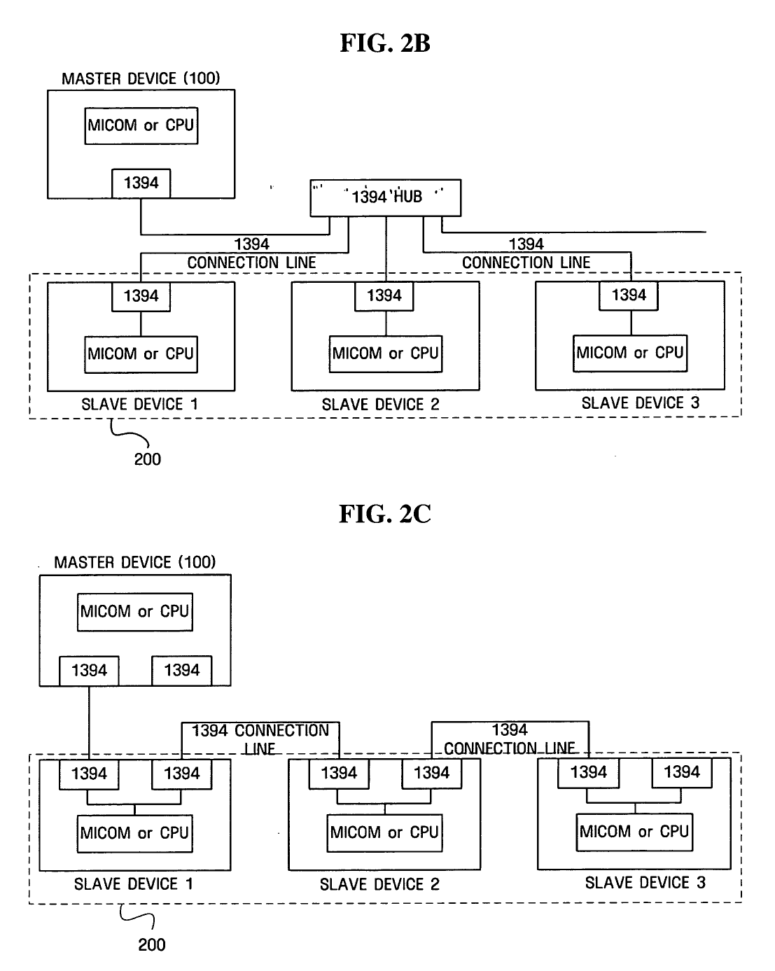

FIG. 2A shows an example of a system providing error information within an XHT network according to an exemplary embodiment of the present invention and FIGS. 2B and 2C show examples of connecting a master device with slave devices through 1394 connection lines according to another exemplary embodiment of the present invention.

Referring to FIG. 2A, a master device 100 and a plurality of slave devices 200 existing in an XHT network include A/V cables (indicated by solid lines) transmitting and receiving a video or audio signal as well as communication control lines (indicate by dotted lines) using a separate protocol to transmit data packets, such as IEEE 1394 connection lines or RS-232C cables.

Here, through the communication control lines, device information or connection state information on the devices existing on the XHT network may be transmitted and received and operation commands that can control the slave devices 200 may be delivered. The communication control line can use a variety of physical layers including IEEE 1394, RS-232C, Ethernet, and Power Line Communication (PLC).

Referring to FIGS. 2B and 2C, a master device 100 controls all slave devices 200 existing within an XHT network. Here, the master device 100 can be understood as an A/V device having a display function such as a DTV or computer.

That is, the master device 100 receives a remote control signal generated by a user and controls a corresponding slave device among the slave devices 200 by interpreting the input signal.

For example in FIG. 2B, when the user uses a remote control to issue a command to control a predetermined slave device (e.g., slave device 200A), the master device 100 that receives the command interprets the command and controls an appropriate slave device, e.g., slave device 200A, according to the interpreted command. In this case, the master device 100 transmits a control command to the slave device 200A via the communication control line.

Upon receipt of a user's request for error information on the predetermined slave device 200A, the master device 100 also transmits an error information request message to the slave device 200A and displays error information received from the slave device 200A on a screen.

For example, when a user generates a command requesting error information of a predetermined slave device 200A (e.g., DVD player) through a remote control, the master device 100 that receives an error information request signal generated by the user interprets the received signal and transmits a message requesting the error information to the slave device 200A.

The slave device 200A that receives the error information request message from the master device 100 checks error information for transmission to the master device 100 that then displays the same information on a screen.

Upon a user's request, the master device 100 also displays the slave devices 200 (connected to the master device 100) that can be controlled among slave devices existing on the XHT network on the screen, thus allowing the user to identify the slave devices available for use. A slave device among the slave devices 200 that receives a control command from the master device 100 performs an operation according to the control command.

Here, each of the slave devices 200 can be one of an AV receiver, AV hard disk drive (HDD), Digital Video Home System (DVHS), DVD player, DVD recorder, DVD Combo, video cassette recorder (VCR), cable STB, satellite STB, and terrestrial STB. Although FIG. 2A shows an STB, DVHS and A/V HDD as exemplary devices, the present invention is not limited thereto.

More specifically, upon receipt of an error information request message, the slave devices 200 check existence of an error and transmit error information to the master device 100 if an error has occurred.

Alternatively, each of the slave devices 200 may periodically check existence of an error at predetermined time intervals for transmission to the master device 100. In this case, if an error has occurred in one of the slave devices 200, that slave device immediately provides the master device 100 with information about the error, thereby allowing the user to identify the error of that slave device 200.

FIG. 2B also shows an example of connecting the master device 100 with the slave devices 200 through 1394 connection lines using a hub 300 and FIG. 2C shows an example of connecting the master device 100 with the slave devices 200 in a daisy-chain structure.

Referring to FIG. 2B, a 1394 hub connects the master device 100 and the slave devices together through 1394 connection lines. While each device is assigned a unique ID, i.e., global unique ID (GUID) through a mechanism established by the IEEE 1394 standard, the assigned ID needs to be reset when a device is added or deleted. A microcomputer (micom) is a central processing module embedded in home appliances and performs the same function as a central processing unit (CPU). As shown in FIG. 2C, the slave devices may be connected to the master device 100 in a daisy-chain fashion using IEEE 1394 connection lines. To establish this connection, a 1394 port of the master device 100 is connected to a first 1394 port of the slave device 200A and a second 1394 port of the slave device 200A is connected to a first 1394 port of the slave device 200B.

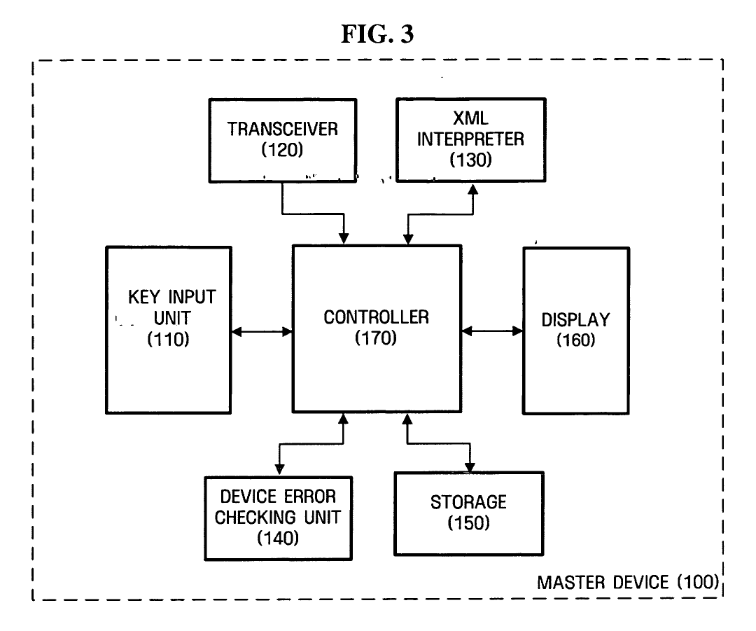

FIG. 3 is a block diagram of a master device 100 in an XHT network providing error information according to an exemplary embodiment of the present invention. This exemplary embodiment of the present invention will now be described, focusing on a process of transmitting a message requesting error information to a slave device within the XHT network and displaying error information received from the slave device on a screen.

Referring to FIG. 3, the master device 100 includes a key input unit 110, a transceiver 120, an XML interpreter 130, a device error checking unit 140, a storage 150, a display 160, and a controller 170.

The key input unit 110 receives a key signal generated by a user. The user may generate a predetermined key signal using a remote control, a touch screen, or other input device.

Upon a user's request for error information of a predetermined slave device, e.g., slave device 200A, the transceiver 120 transmits a message requesting the error information to the slave device 200A and receives the error information from the slave device 200A.

The XML interpreter 130 interprets a document containing the error information received from the slave device.

The storage 150 stores information about all slave devices existing on an XHT network such as device information, location information, connection state information, and icon images.

The storage 150 also stores an operation command corresponding to a key selected by the user. The operation commands can be stored in a mapping table.

Specifically, when a predetermined key code value is generated upon user's selection of a key, the controller 170 retrieves an operation command corresponding to the key code value from the mapping table and transmits the retrieved operation command to a corresponding one of slave devices 200.

The display 160 displays error information interpreted by the XML interpreter 130 on a screen. When the user requests for retrieval of a certain slave device existing on the XHT network, the display 160 also displays image icons for predetermined slave devices 200 connected to the master device 100 on the screen.

When the key input unit 110 receives a key signal generated by the user, the controller 170 analyzes the received key signal and controls a corresponding one of the slave devices 200 according to the analyzed key signal.

More specifically, upon receipt of a key signal generated by the user from the key input unit 110, the controller 170 analyzes the received key signal and recognizes a corresponding operation command issued by the user.

When the recognized operation command is a key signal requesting control information of a predetermined slave device, e.g., slave device 200A, the controller 170 allows the transceiver 120 to transmit a message requesting device error information to the predetermined slave device 200A.

Upon receipt of information from the transceiver 120, the controller 170 allows the XML interpreter 130 to interpret the received information while requesting the display 160 to display the interpreted information on the screen.

For example, upon receipt of a document containing error information from the slave device 200A through the transceiver 120, the controller 170 requests the XML interpreter 130 to interpret the document containing error information and displays the interpreted error information on the screen through the display 160.

The controller 170 also performs discovery and description processes to collect information about the slave devices existing on the XHT network. Here, the discovery process is performed for the master device 100 to find a slave device existing on the XHT network. The description process is performed for the master device 100 to analyze a service description XML file received from a slave device and obtain service functions needed to control the slave device.

The device error checking unit 140 checks an error of the master device 100. That is, upon a user's request for error information of the master device 100 or at predetermined time intervals, the device error checking unit 140 checks existence of an error within the master device 100 itself and transmits the error information to the controller 170 for display.

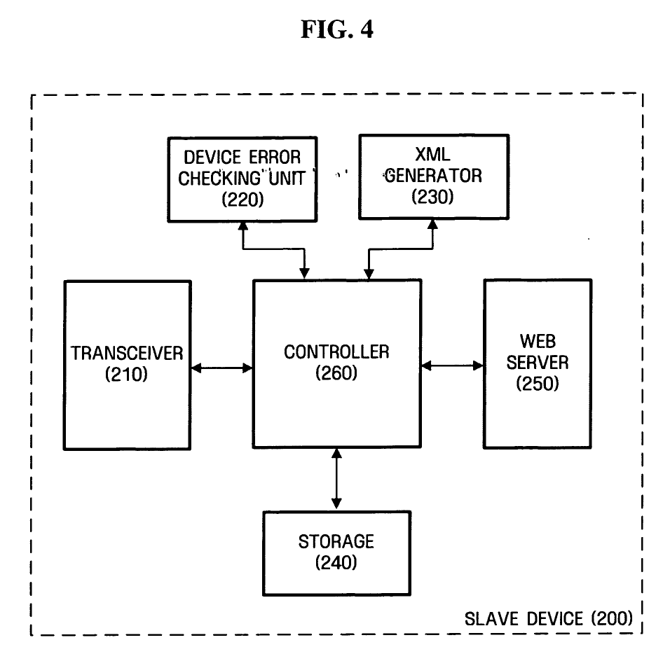

FIG. 4 is a block diagram of a slave device, e.g., slave device 200A, in an XHT network providing error information according to an exemplary embodiment of the present invention. The exemplary embodiment of the present invention will now be described, focusing on a process of generating error information and transmitting the error information to a master device in the XHT network.

Referring to FIG. 4, the slave device 200A includes a transceiver 210, a device error checking unit 220, an XML generator 230, a storage 240, a web server 250, and a controller 260.

The transceiver 210 receives a message requesting error information from the master device 100 and transmits a response message (i.e., error information) to the request message to the master device 100.

The device error checking unit 220 may check existence of an error upon request of the master device 100 for error information or periodically check an error at predetermined time intervals upon request of the controller 260.

For example, when the slave device is a DVD player, the device error checking unit 220 may request the controller 260 to play the DVD player in order to check whether the DVD player operate normally and checks existence of an error during operation by sensing a signal output while playing the DVD player.

The XML generator 230 creates a document containing error information checked by the device error checking unit 220. Here, the error information is described in an XML file according to XSD syntax.

The storage 240 stores device information and error information as well as device information and location information of the master device 100. Here, the device information and the location information of the master device 100 are used for transmitting the error information of the slave device 200A to the master device 100.

The web server 250 transmits an HTTP command to the master device 100. That is, an A/V device compliant with the XHT standard includes the web server 250 and a device controller converting an HTTP command to a device operation command, thereby allowing the master device 100 to perform operation corresponding to the HTTP command received from the web server 250.

If the transceiver 210 receives a message requesting error information of a device from the master device 100, the controller 260 instructs the device error checking unit 220 to check existence of an error.

When an error is checked by the device error checking unit 220, the controller 260 requests the XML generator 230 to create a document containing error information while allowing the transceiver 210 or the web server 250 to transmit the created error information to the master device 100.

The controller 260 controls operation of the device error checking unit 220 so that it periodically checks existence of an error at predetermined time intervals. In this way, the slave device 200A can check existence of an internal error and inform the user of error information if the error information is checked.

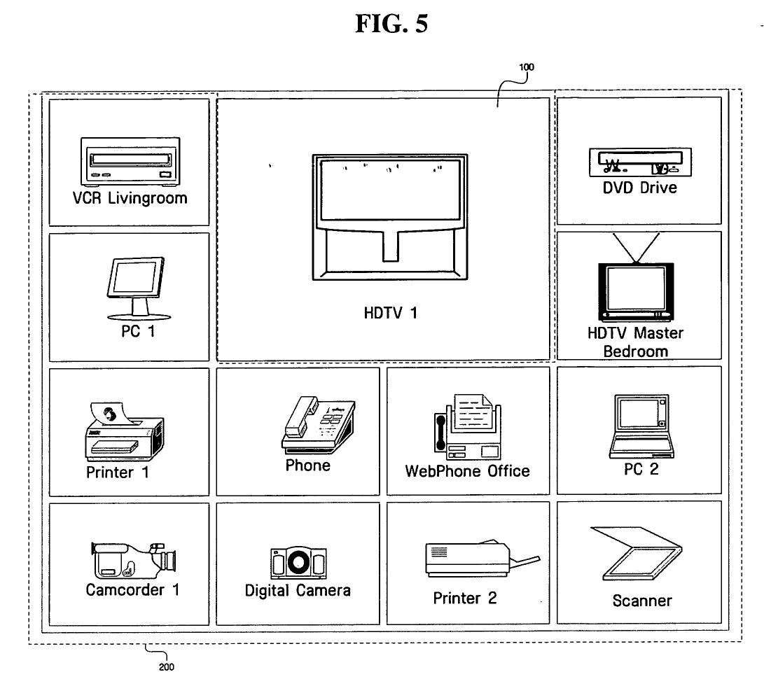

FIG. 5 shows an example of displaying predetermined slave devices 200 with a master device 100 existing within an XHT network on a screen of a master device 100 in the XHT network providing error information according to an exemplary embodiment of the present invention.

As shown in FIG. 5, image icons for predetermined slave devices 200 within the XHT network connected to the master device 100 are displayed on the screen of the master device 100. Here, a user can select a desired icon from the displayed image icons.

For example, when the user uses a remote control to request retrieval of slave devices 200 existing on the XHT network, the master device 100 inputs and analyzes a remote control key signal generated by the user.

Then, the master device 100 displays icons for the predetermined slave devices 200 connected to the master device 100 according to the analyzed result. That is, the controller 170 retrieves device graphic information on the slave devices 200 connected to the master device 100 from the storage 150 and displays the icons on the screen through the display 160.

Then, the user selects an icon for a slave device, e.g., slave device 200A, on which error information is desired from the icons displayed on the screen of the master device 100. Here, the user selects the icon for the desired slave device 200A through a remote control or a touch screen.

Upon the user's selection, the master device 100 retrieves information of the slave device 200A corresponding to the selected icon from the storage 150, transmits a message requesting error information to the slave device 200A based on the retrieved information, receives the error information from the slave device 200A, and displays the same information on its screen.

Thus, the user can identify the slave devices 200 existing in the XML network through the master device 100 and be easily provided with error information by selecting the icon for the desired slave device 200A from the icons displayed on the screen of the master device 100.

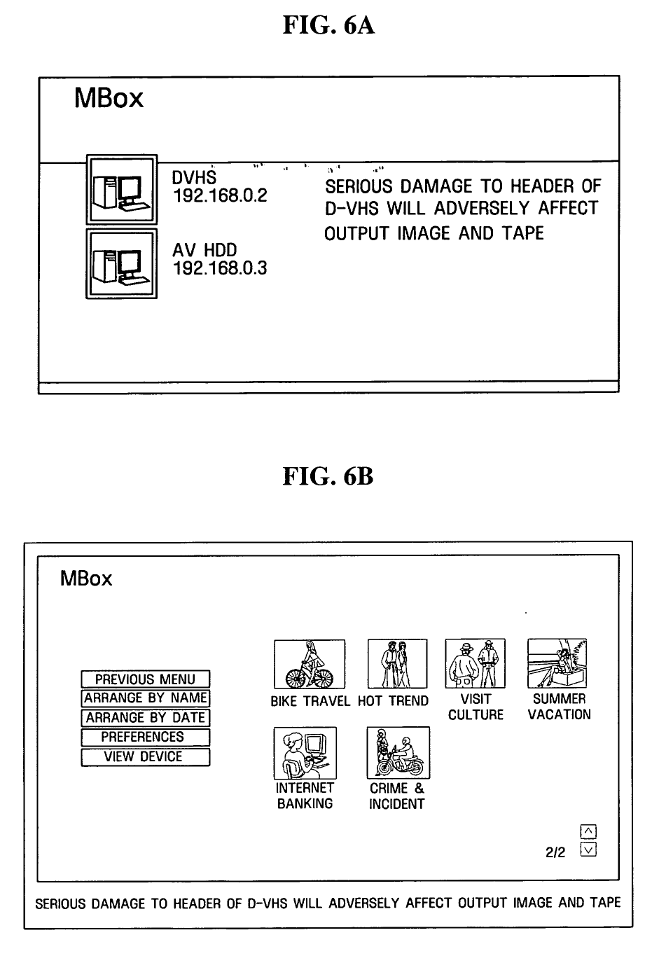

FIGS. 6A and 6B shows examples of displaying error information on a screen of a master device within an XHT network providing error information according to an exemplary embodiment of the present invention.

Referring to FIGS. 6A and 6B, when an error occurs in a DVHS that is a slave device, e.g., slave device 200A, existing in the XHT network, the DVHS transmits error information to a master device 100 that then displays the received error information of the DVHS on its screen.

For example, if it is checked that an error has occurred in a header of the DVHS slave device 200A, upon request of the master device 100 for error information or through a periodic check performed by the slave device 200A itself, an XML generator 230 of the D-VHS creates a document containing error information for transmission to the master device 100.

Then, the master device 100 interprets the error information received from the slave device 200A and displays the interpreted error information and a problem resulting from the error on the screen. Here, the error information of the DVHS may be displayed at a predetermined position on the screen of the master device 100.

For example, as shown in FIG. 6A, an error message stating “SERIOUS DAMAGE TO HEADER OF D-VHS WILL ADVERSELY AFFECT OUTPUT IMAGE AND TAPE” may be displayed on the center of the screen of the master device 100, thereby allowing a user to be informed of error information of the DVHS and the possible situations resulting from the error.

As shown in FIG. 6B, current error information of a DVHS and possible situations resulting from an error may be displayed at the bottom of the screen when a user desires to play multimedia contents, thus stopping a user from using the DVHS or allowing the user to request for an A/S.

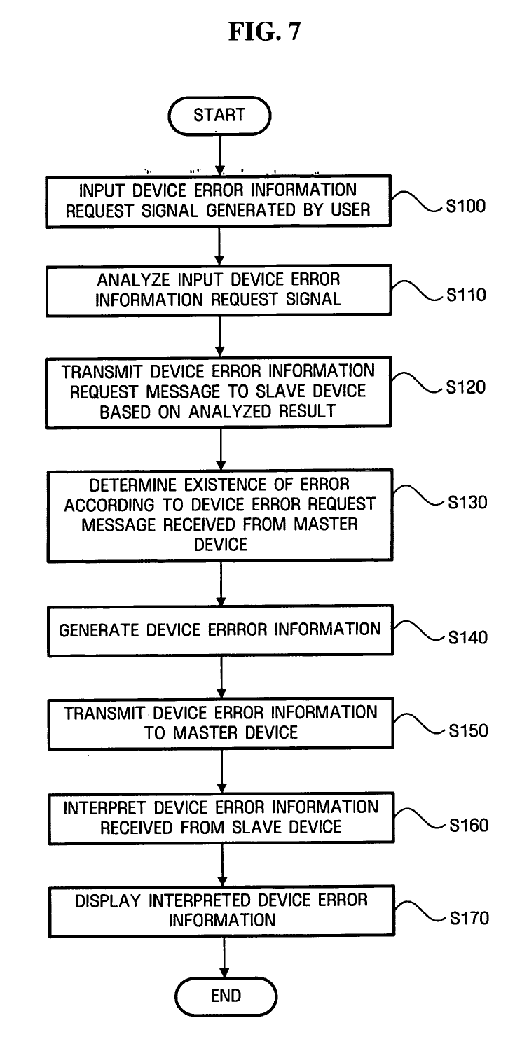

FIG. 7 is a flowchart illustrating a process of a slave device providing error information upon request from a master device in a method of providing error information within an XHT network according to an exemplary embodiment of the present invention. The exemplary process in FIG. 7 will be described below with reference to the exemplary structure of a master device and a slave device as shown in FIGS. 3 and 4.

First, when a key code value generated by a user is input through the key input unit 110 in operation S100, the controller 170 analyzes the received key code value.

When the user requests information of predetermined slave devices existing on the XHT network, the controller 170 displays image icons for the slave devices stored in the storage 150 through the display 160.

When a user selects an icon for a slave device, e.g., slave device 200A, on which error information is desired from the icons for the slave devices 200 displayed on the screen, the key input unit 110 receives a key code value generated upon the user's selection of a key and the controller 170 checks the slave device 200A associated with the icon corresponding to the received key code value in operation S110.

In operation S120, the controller 170 transmits a message requesting error information to the checked slave device 200A.

Then, the transceiver 210 of the slave device 200A receives the message requesting the error information from the master device 100 and transmits the request message to the controller 260.

Then, the controller 260 requests the device error checking unit 220 to check existence of an error according to the request message.

In operation 130, the device error checking unit 220 checks existence of an error and transmits error information to the controller 260 if an error has occurred. Then, the controller 260 transmits the error information received from the device error checking unit 220 to an XML generator 230 and requests the XML generator 230 to create a document containing the error information.

In operation S140, the XML generator 230 creates the document containing the error information in an XML file according to XSD syntax.

In operation S150, the controller 260 transmits the document containing the error information to the master device 100 through the transceiver 210.

Then, a transceiver 120 of the master device 100 receives the document from the slave device 200A and transmits the same to the controller 170.

Upon receipt of the document, the controller 170 transmits the same to an XML interpreter 130 and requests the XML interpreter 130 to interpret the error information contained in the document. In operation S160, the XML interpreter 130 then interprets the XML document according to XSD syntax and transmits the interpreted error information to the controller 170.

In operation S170, the controller 170 displays the interpreted error information on the screen through the display 160.

The master device 100 and the slave devices 200 existing in the XHT network are connected together through communication control lines (e.g., IEEE 1394 connection lines), thus allowing the master device 100 to control the slave devices 200. Furthermore, it is possible to immediately check existence of an error of the slave devices 200 by displaying error information of the slave devices 200 through the master device 100 having a display function.

The user can also conveniently identify existence of an error, obtain error information of the slave devices 200, and request an after-service upon the occurrence of an error.

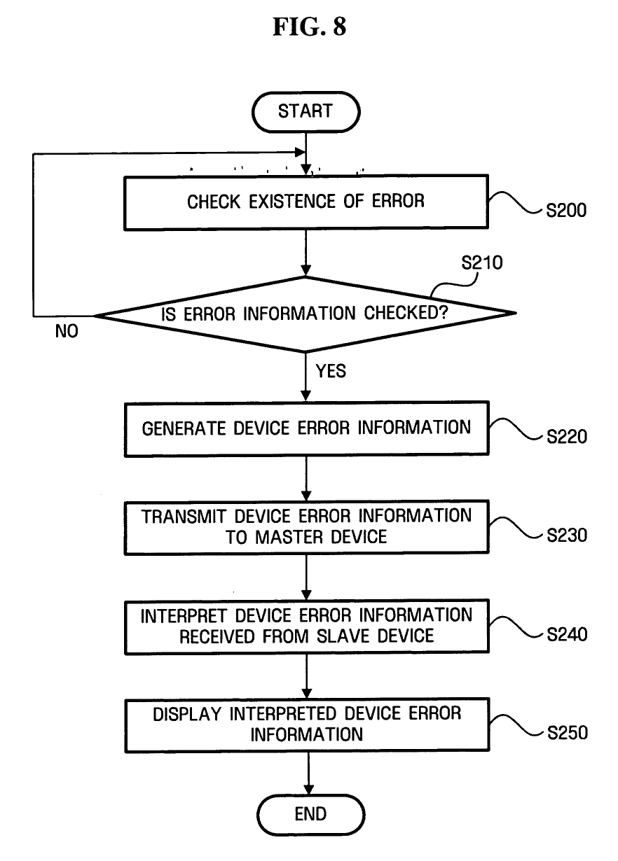

FIG. 8 is a flowchart illustrating a process of a slave device providing error information to a master device after periodically checking existence of an error in a method of providing error information within an XHT network according to an exemplary embodiment of the present invention. The exemplary process in FIG. 8 will also be described below with reference to the exemplary structure of a master device and a slave device as shown in FIGS. 3 and 4.

Referring to FIG. 8, first, in operation S200, the device error checking unit 220 of the slave device 200A periodically checks existence of an error at predetermined time intervals and transmits error information to the controller 260 if an error has occurred. The time intervals may be changed randomly by the user.

Then, the controller 260 transmits the received error information to the XML generator 230 and requests the XML generator 230 to create a document containing the error information.

In operation S220, the XML generator 230 creates the document containing the error information based on the error information checked according to the command of the controller 260. In operation S230, the controller 260 transmits the document containing the error information to the master device 100 through the transceiver 210.

Then, the transceiver 120 of the master device 100 receives the document from the slave device 200. Upon receipt of the document, the controller 170 transmits the same to the XML interpreter 130 and requests the XML interpreter 130 to interpret the error information contained in the document.

In operation S240, the XML interpreter 130 then interprets the XML document according to XSD syntax and transmits the interpreted error information to the controller 170. In operation S250, the controller 170 displays the interpreted error information on the screen through the display 160.

As described above, even as no request for error information is received from the master device 100, the slave devices 200 internally check existence of an error and transmit error information to the master device 100 and to the user if an error has occurred, thereby allowing the user to promptly identify the existence of errors and error states of all devices in the XHT network.

A device, a system, and a method for providing error information in an XHT network have at least one of the following advantages.

First, by receiving a key signal generated by a user, analyzing the key signal, and transmitting a command corresponding to the key signal to a corresponding slave device, a master device can control slave devices in the XHT network.

Second, when the user uses a remote control to request error information from a master device, the master device transmits a user's command to a corresponding slave device, receives the error information from the slave device, and displays the error information to the user, thereby allowing the user to promptly obtain the error information of the slave device and easily manage error information of slave devices in the XHT network.

Third, a slave device transmits error information to a master device after periodically checking the existence of an error at predetermined time intervals, thus allowing the user to immediately identify and check the existence of errors of slave devices within the XHT network.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A master device existing on an expandable Home Theater (XHT) network, the master device comprising:
a key input unit which receives a key code value;
a transceiver which transmits a signal requesting error information to a slave device connected to the master device through the XHT network and receives the error information in response to the signal requesting error information;
an interpreter that interprets the error information; and
a display that displays the interpreted error information on a screen of the master device.

2. The master device of claim 1, wherein the slave device is a predetermined slave device.

3. The master device of claim 1, wherein the interpreter comprises an Extensible Markup Language (XML) interpreter.

4. The master device of claim 1, further comprising a controller which recognizes the key code value, controls the transceiver to transmit the signal requesting the error information to the slave device, requests the interpreter to interpret the error information, and requests the display to display the interpreted error information on the screen.

5. The master device of claim 1, further comprising:
a storage unit; and
a controller which analyzes the key code value and retrieves an operation command corresponding to the key code value from the storage, controls the transceiver to transmit the signal requesting the error information, corresponding to the operation command, to the slave device, requests the interpreter to interpret the error information, and requests the display to display the interpreted error information on the screen,
wherein the storage that stores information comprising:
operation commands corresponding to key code values;
device information, location information and connection state information of the slave device that are used to transmit the request signal to the slave device; and
icon images of the master device and the slave device displayed on the display.

6. The master device of claim 1, further comprising a device error checking unit that checks an error of the master device upon request of the user or at predetermined time intervals.

7. A slave device existing on an expandable Home Theater (XHT) network, comprising:
a device error checking unit which checks existence of an error;
an error information generator which creates a document containing error information received from the device error checking unit; and
a transceiver that provides the error information to a master device connected to the slave device through the XHT network.

8. The slave device of claim 7, wherein the error information generator creates the document containing the error information in an XML format.

9. The slave device of claim 7, wherein the device error checking unit checks the existence of the error upon request of the master device or at predetermined time intervals.

10. The slave device of claim 7, further comprising a controller which instructs the device error checking unit to check the existence of the error, requests the error information generator to create the error information, and controls the transceiver to provide the error information to the master device.

11. The slave device of claim 10, further comprising a storage unit that stores information comprising:
the error information; and
information on the master device, comprising device information, location information and connection state information that are used to transmit the error information to the master device.

12. The slave device of claim 11, further comprising a web server, wherein the error information is transmitted to the master device through one of the web server and the transceiver.

13. A system providing error information within an expandable Home Theater (XHT) network, the system comprising:
a master device which requests error information from a slave device connected through the XHT network; and
the slave device which transmits the error information to the master device.

14. The system of claim 13, wherein the master device comprises:
a key input unit which receives a key code value;
a transceiver which transmits a signal requesting error information to the slave device and receives the error information in response to the signal requesting error information;
an interpreter which interprets the error information; and
a display which displays the interpreted error information on a screen of the master device.

15. The system of claim 14, wherein the master device further comprises a device error checking unit which checks an error of the master device upon request of the user or at predetermined time intervals.

16. The system of claim 13, wherein the slave device comprises:
a device error checking unit which checks existence of an error;
an error information generator which creates a document containing error information received from the device error checking unit; and
a transceiver which provides the error information to the master device connected to the slave device through the XHT network.

17. The system of claim 16, wherein the device error checking unit checks the existence of an error upon request of the master device or at predetermined time intervals.

18. A method for providing error information within an eXpandable Home Theater (XHT) network, the method comprising:
checking existence of an error in at least one slave device connected to a master device through the XHT network;
transmitting error information to the master device if the error occurs in the slave device;
interpreting the error information; and
displaying the error information on a screen of the master device.

19. The method of claim 18, wherein the slave device is a predetermined slave device.

20. The method of claim 18, wherein the error information is generated in an Extended Markup Language (XML) format.

21. The method of claim 18, wherein the slave device checks the existence of the error upon request of a user or at predetermined time intervals.

22. The method of claim 18, further comprising:
receiving at the slave device a request for error information from the master device,
wherein the checking the existence of the error at the slave device is performed according to the received request message.
